(19) United States
(12) Patent Application Publication
(10) Pub. No.: US 2017/0118867 A1
(43) Pub. Date: Apr. 27, 2017

(54) MOBILE TERMINAL AND MIDDLE FRAME THEREOF

(71) Applicants: LE HOLDINGS (BEIJING) CO., LTD., Beijing (CN); Lemobile Information Technology (Beijing) Co., Ltd, Beijing (CN)

(72) Inventor: Jizeng CHANG, Beijing (CN)

(21) Appl. No.: 15/236,280

(22) Filed: Aug. 12, 2016

Related U.S. Application Data
(63) Continuation of application No. PCT/CN2016/088392, filed on Jul. 4, 2016.

(30) Foreign Application Priority Data
Oct. 22, 2015 (CN) 201510694444.4

(51) Int. Cl. H05K 7/20; G06F 1/20; H04M 1/02

(52) U.S. Cl. CPC H05K 7/20218; H04M 1/026; G06F 1/203

(57) ABSTRACT

An embodiment of the present disclosure provides a mobile terminal and a middle frame thereof The middle frame of the mobile terminal includes a middle frame body in which a plurality of heat dissipating conduits are provided in a hollowing manner, the heat dissipating conduits are filled with a heat-conducting medium to absorb heat dissipated from individual functional modules in the mobile terminal. By means of the mobile terminal and the middle frame thereof provided by the embodiment of the present disclosure, in a case where the thickness of the mobile terminal is not increased, heat dissipated from individual functional modules may be absorbed by filling the heat-conducting medium in the heat dissipating conduits to dissipate heat from the individual functional modules, a heat dissipating demand of the individual functional modules is satisfied, and working of the individual functional modules at a normal temperature is guaranteed.

### CROSS-REFERENCE TO RELATED APPLICATIONS

The present disclosure is a continuation of International Application No. PCT/CN2016/088392, filed on Jul. 4, 2016; which is based upon and claims priority to Chinese Patent Application No. 201510694444.4, entitled “MOBILE TERMINAL AND MIDDLE FRAME THEREOF”, filed on Oct. 22, 2015, the entire contents of all of which are incorporated herein by reference.

### FIELD OF TECHNOLOGY

The present disclosure generally relates to the field of mobile communication, and particularly relates to a mobile terminal and a middle frame thereof.

### BACKGROUND

At present, as mobile terminals such as mobile phones, tablet personal computers and portable readers become thinner, spacing among individual functional modules becomes smaller. However, individual functional modules, for example, a central processing unit, a battery and a display screen, produce a large amount of heat during running, and the mobile terminal is heated if heat may not be immediately dissipated.

At present, to solve the heat dissipating problem of the individual functional modules, heat-conducting pipes are disposed between individual functional modules and a middle frame, one ends of the heat-conducting pipes are embedded or affixed on the middle frame, and the other ends are welded on shields of the individual functional modules. However, there are many functional modules in the mobile terminal, and therefore, the number of the heat-conducting pipes required to be mounted is correspondingly increased. On the one hand, a mounting difficulty of the heat-conducting pipes is relatively high, a mounting efficiency is relatively low; on the other hand, as a number of the mounted heat-conducting pipes is increased, an overall thickness of the mobile terminal may be increased.

Therefore, at present, a technical problem urgently solved by those skilled in the art is as follows: how to cool individual functional modules and guarantee that the individual functional modules work at a normal temperature in a case where a thickness of the mobile terminal is not increased.

### SUMMARY

An embodiment of the present disclosure discloses a mobile terminal and a middle frame thereof, which are used for solving technical problems that a heat dissipating effect of individual functional modules is poor and the mobile terminal is easily heated in a case where a thickness of the mobile terminal is not increased in the prior art.

According to one aspect of the present disclosure, the embodiment of the present disclosure discloses a middle frame of the mobile terminal, including a middle frame body in which a plurality of heat dissipating conduits are provided in a hollowing manner, wherein the heat dissipating conduits are filled with a heat-conducting medium to absorb heat dissipated from individual functional modules in the mobile terminal.

According to another aspect of the present disclosure, the embodiment of the present disclosure further discloses a mobile terminal, including the middle frame described in any one of the above.

By means of the mobile terminal and the middle frame thereof provided by the embodiment of the present disclosure, in a case where the thickness of the mobile terminal is not increased, heat dissipated from individual functional modules may be absorbed by filling the heat-conducting medium in the heat dissipating conduits to dissipate heat from the individual functional modules, a heat dissipating demand of the individual functional modules is satisfied, and working of the individual functional modules at a normal temperature is guaranteed.

The foregoing illustration is only an overview of a technical solution of the present disclosure. In order to clearly illustrate the technical means of the present disclosure to ensure the present disclosure is implementable according to content of the specifications, and in order to make the above and other purposes, characteristics and advantages of the present disclosure more apparent to understand, embodiments of the present disclosure are specifically illustrated as follows.

### BRIEF DESCRIPTION OF THE DRAWINGS

In order to more clearly illustrate the technical solution in an embodiment of the present disclosure or the prior art, drawings required to be used in the description of the embodiment or the prior art will be briefly introduced in the following; it is obvious that the drawings described in the following are only related to some embodiments of the present disclosure. Other drawings may be obtained according to these drawings by those ordinarily skilled in the art without paying creative work.

FIG. 1 is a perspective view of a structure of a middle frame of a mobile terminal according to an embodiment of the present disclosure.

FIG. 2 is a schematic cross-sectional view of a structure of a middle frame of a mobile terminal according to an embodiment of the present disclosure.

### DESCRIPTION OF THE EMBODIMENTS

For the purpose of making objects, technical schemes and advantages of embodiments of the present disclosure more clear, clear and complete description will be made to technical schemes of the present disclosure in conjunction with corresponding drawings in the embodiment of the present disclosure. Obviously, the described embodiments are merely a part of the embodiments of the present disclosure and not all the embodiments. Based on the embodiments of the present disclosure, all other embodiments obtained by those ordinarily skilled in the art without paying creative work fall within the protection scope of the present disclosure.

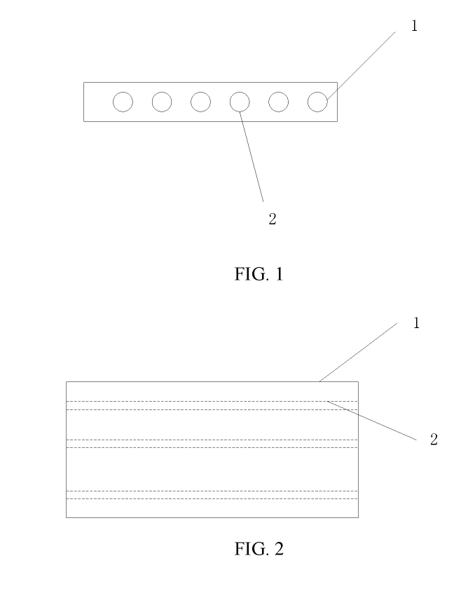

FIG. 1 shows a perspective view of a structure of a middle frame of a mobile terminal according to an embodiment of the present disclosure.

FIG. 2 shows a schematic cross-sectional view of a structure of a middle frame of a mobile terminal according to an embodiment of the present disclosure.

To reduce temperatures of individual functional modules, satisfy a heat dissipating demand of the individual functional modules and guarantee that the processor works at a normal temperature in a case where a thickness of a mobile terminal is not increased, an embodiment of the present disclosure provides a middle frame of a mobile terminal. As shown in FIG. 1 and FIG. 2, the middle frame includes a middle frame body 1 in which a plurality of heat dissipating conduits 2 are provided in a hollowing manner, the heat dissipating conduits 2 are filled with a heat-conducting medium to absorb heat dissipated from individual functional modules in the mobile terminal.

In the embodiment of the present disclosure, the heat dissipating conduits may be formed into the middle frame by employing laser engraving, corrosive engraving or other micro-channel fabricating processes. It is noted that, a diameter of the heat dissipating conduits may be ½ of a thickness of the middle frame to guarantee that the middle frame is sufficient in strength to carry the individual functional modules. Certainly, a ratio of the diameter of the heat dissipating conduits to the thickness of the middle frame may also be other numerical value.

Regions with a relatively high temperature on the middle frame may be provided with the above heat dissipating conduits, and the individual heat dissipating conduits may be distributed in the middle frame in parallel and may also be disposed in the middle frame in a bending manner. On the one hand, the fabricating process of the heat dissipating conduits with a bending shape is relatively complicated; on the other hand, the flow velocity of a liquid at a corner may be weakened, so that a heat dissipating effect is affected; therefore, the present disclosure preferably uses linear heat dissipating conduits, and certainly may employ heat dissipating conduits of other shapes.

Firstly, the heat dissipating conduits are formed into the middle frame by the above micro-channel fabricating process, then the heat-conducting medium is filled in the heat dissipating conduits, and finally, the heat dissipating conduits may be closed by a thermoplastic process.

Wherein the heat-conducting medium may include but not limited to water, alcohol and a refrigerant, or employ any other liquids which may be configured to conduct heat.

To enhance a stability of the individual functional modules, the middle frame of the mobile terminal, which is provided by the embodiment of the present invention, further includes a shield disposed on the middle frame, which is configured to fix the individual functional modules. Therefore, the individual functional modules are prevented from moving on the middle frame, and the stability of the individual functional modules is improved.

A gap may exist between the middle frame and the shield to affect heat conduction; to increase a heat-conducting efficiency, a heat-conducting gel may be applied between the middle frame and the shield, and heat dissipated from the individual functional modules is conducted to the middle frame by the shield and the heat-conducting gel. It is noted that the above individual functional modules include but are not limited to central processing units, batteries and display screens.

By means of the mobile terminal and the middle frame thereof provided by the embodiment of the present disclosure, in a case where the thickness of the mobile terminal is not increased, heat dissipated from individual functional modules may be absorbed by filling the heat-conducting medium in the heat dissipating conduits to dissipate heat from the individual functional modules, a heat dissipating demand of the individual functional modules is satisfied, and working of the individual functional modules at a normal temperature is guaranteed

In addition, an embodiment of the present invention provides a mobile terminal, including the above middle frame. Because individual functional modules work at a normal temperature, the mobile terminal is prevented from being heated.

Apparatus embodiments described above are illustrative only, wherein the unit described as a separate part may be or may be not physically separated, a part displayed as the unit may be or may be not a physical unit, may be located in one place, or may be distributed on a plurality of network units. Some or all of the modules may be selected to achieve the objective of the solutions of the embodiments according to actual requirements. Those ordinarily skilled in the art may understand and implement it without paying creative works.

Finally, it should be noted that the foregoing embodiments are merely illustrative of technical solutions of the present disclosure without limitation; although the present disclosure is illustrated in detail with reference to the above embodiments, those ordinarily skilled in the art will appreciate that modifications may be made on the technical solutions cited by the above embodiments, or equivalent substitutions may be made on partial technical features; moreover, these modifications or substitutions will not make the essential of corresponding technical solutions depart from the spirit and scope of the technical solutions in respective embodiments of the present disclosure.

What is claimed is:

1. A middle frame of a mobile terminal, comprising a middle frame body in which a plurality of heat dissipating conduits are provided in a hollowing manner, the heat dissipating conduits are filled with a heat-conducting medium to absorb heat dissipated from individual functional modules in the mobile terminal.

2. The middle frame according to claim 1, wherein the heat dissipating conduits are formed into the middle frame by a micro-channel fabricating process.

3. The middle frame according to claim 1, wherein the heat-conducting medium comprises water, alcohol and a refrigerant.

4. The middle frame according to claim 1, wherein the heat dissipating conduits are distributed in the middle frame in parallel.

5. The middle frame according to claim 1, further comprising a shield disposed on the middle frame, wherein the shield is configured to fix the individual functional modules.

6. The middle frame according to claim 5, wherein a heat-conducting gel is applied between the middle frame and the shield, and heat dissipated from the individual functional modules is conducted to the middle frame by the shield and the heat-conducting gel.

7. The middle frame according to claim 1, wherein the individual functional modules comprise central processing units, batteries and display screens.

8. A mobile terminal, comprising the middle frame, wherein the middle frame comprises a middle frame body in which a plurality of heat dissipating conduits are provided in a hollowing manner, the heat dissipating conduits are filled with a heat-conducting medium to absorb heat dissipated from individual functional modules in the mobile terminal.

9. The mobile terminal according to claim 8, wherein the heat dissipating conduits are formed into the middle frame by a micro-channel fabricating process.

10. The mobile terminal according to claim 8, wherein the heat-conducting medium comprises water, alcohol and a refrigerant.

11. The mobile terminal according to claim 8, wherein the heat dissipating conduits are distributed in the middle frame in parallel.

12. The mobile terminal according to claim 8, further comprising a shield disposed on the middle frame, wherein the shield is configured to fix the individual functional modules.

13. The mobile terminal according to claim 12, wherein a heat-conducting gel is applied between the middle frame and the shield, and heat dissipated from the individual functional modules is conducted to the middle frame by the shield and the heat-conducting gel.

14. The mobile terminal according to claim 8, wherein the individual functional modules comprise central processing units, batteries and display screens.
